(19) United States
(12) Patent Application Publication
(10) Pub. No.: US 2003/0107107 A1
(43) Pub. Date: Jun. 12, 2003

(54) High fill factor CMOS image sensor

(76) Inventors: Hsien-Chun Chang, Chilung (TW); Ya-Chin King, Chungli (TW)

Correspondence Address: J.C. Patents, Inc., Suite 250, 4 Venture, Irvine, CA, 92618, US

(21) Appl. No.: 10/068,228

(22) Filed: Feb. 6, 2002

(30) Foreign Application Priority Data
Dec. 7, 2001 (TW) 90130292

(51) Int. Cl. H01L 27/082

(52) U.S. Cl. 257/590

(57) ABSTRACT

A CMOS image sensor structure for improving the fill factor due to design rule limitations of a conventional image sensor that incorporates a photo diode and three N-type transistors. In a first embodiment, two N-type transistors are changed to P-type transistors and the P-type transistors are formed directly within the N-well of the photo diode. In a second embodiment, the other reset N-type transistor is changed to a reset diode and the reset diode is also formed directly within the N-well of the photo diode. In a third embodiment, the reset diode and the source follower transistor are implemented using a single transistor. In addition, the output selection transistors inside all three types of CMOS image sensor structures may be deleted to increase the fill factor even further.

### CROSS-REFERENCE TO RELATED APPLICATION

This application claims the priority benefit of Taiwan application serial no. 90130292, filed Dec. 7, 2001.

### BACKGROUND OF THE INVENTION

1. Field of Invention

The present invention relates to a complementary metal-oxide-semiconductor (CMOS) image sensor structure. More particularly, the present invention relates to a CMOS image sensor having a higher fill factor.

2. Description of Related Art

Most active photo diode image sensors at least include a photo diode, a reset transistor, a source follower transistor and an output selection transistor. The photo diode is a junction device formed by joining an N-doped and a P-doped semiconductor region together. When the reset transistor is switched on, the N-doped region is charged to a reset potential level. On the other hand, when the reset transistor is shut, the photo diode is in a floating state such that the N⁺/P junction produces a depletion region. If the depletion region is illuminated by light, the electron-hole pairs generated inside the depletion region are pulled apart by local electric field such that electrons migrate towards the N-doped region so that potential at the N-doped region drops. The degree of dropping in the electric potential at the N-doped region reflects the strength of the impinging light beam. Since only electric charges produced inside the depletion region are pulled apart by the electric field, the larger the depletion region the greater will be the drop in potential for a light beam of equal strength. Hence, sensitivity of the photo diode depends very much on the width of the depletion region. However, the N-doped region is a heavily doped region with a narrow depletion width. Thus, opto-electrical conversion efficiency in such photo diode is usually low.

To improve conversion efficiency of a photo diode, an N-well inside a P-type substrate may be used. Since the N-well is a lightly doped region, a larger depletion region is formed when proper voltage is applied. With a higher opto-electric conversion efficiency, sensitivity of the image sensor will increase. However, due to design rule limitations, the smallest dimension of the N-well is still relatively large. Moreover, according to the design rules, distance of separation between the other three N-type transistors (N-channel MOSFET) and the N-well is also quite large leading to a greater overall dimension for this type of image sensing device. Consequently, fill factor of the optical device drops while other properties of the image sensor degenerates.

### SUMMARY OF THE INVENTION

Accordingly, one object of the present invention is to provide a plurality of complementary metal-oxide-semiconductor (CMOS) image sensor structures each having a higher fill factor for increasing opto-electronic conversion efficiency.

To achieve these and other advantages and in accordance with the purpose of the invention, as embodied and broadly described herein, the invention provides a CMOS image sensor structure having a higher fill factor. The image sensor structure includes a photo diode, a reset transistor, a source follower transistor and an output selection transistor. The photo diode receives a light beam to generate a diode voltage. Magnitude of the diode voltage depends on the strength of the light beam. The photo diode is a device created by forming an N-well within a P-type substrate. The reset transistor resets the photo diode to a reset voltage level. The reset transistor is a device created by forming an N-doped region within the P-type substrate but outside the N-well. The source follower transistor provides an output current according to the diode voltage so that voltage level provided by the photo diode may be read. The source follower transistor is a device created by forming a P-doped region within the N-well. The output selection transistor is a switch for choosing whether to read the voltage level from the photo diode or not. Similarly, the output selection transistor is a device created by forming a P-doped region within the N-well.

This invention also provides a second CMOS image sensor structure to increase fill factor. The image sensor structure includes a photo diode, a reset diode, a source follower transistor and an output selection transistor. The photo diode receives a light beam to generate a diode voltage. Magnitude of the diode voltage depends on the strength of the light beam. The photo diode is a device created by forming an N-well inside a P-type substrate. The reset diode resets the photo diode to a reset voltage level. The reset transistor is a device created by forming a P-doped region within the N-well. The source follower transistor provides an output current according to the diode voltage so that voltage level provided by the photo diode may be read. The source follower transistor is a device created by forming a P-doped region within the N-well. The output selection transistor is a switch for choosing whether to read the voltage level from the photo diode or not. Similarly, the output selection transistor is a device created by forming a P-doped region within the N-well.

This invention also provides a third CMOS image sensor structure to increase fill factor. The image sensor structure includes a photo diode, a source follower transistor and an output selection transistor. The photo diode receives a light beam to generate a diode voltage. Magnitude of the diode voltage depends on the strength of the light beam. The photo diode is a device created by forming an N-well inside a P-type substrate. The source follower transistor provides an output current according to the diode voltage so that voltage level provided by the photo diode may be read. The source follower transistor is a device created by forming a source P-doped region and a drain P-doped region within the N-well. The drain P-doped region also serves as a reset diode for resetting the diode voltage to a reset level. The output selection transistor is a switch for choosing whether to read the voltage level from the photo diode or not. Similarly, the output selection transistor is a device created by forming a P-doped region within the N-well.

In addition, all the CMOS image sensor structures for boosting fill factor can combine with any voltage reading circuit so that the output selection transistor may be deleted if necessary.

This invention provides a CMOS image sensor structure that aims at improving design rule limitations. The conventional N-type source follower transistor and output selection transistor are replaced by P-type transistors and the P-type transistors are formed inside the N-well that constitutes the photo diode. Aside from some area occupied by the transistor, the entire N-well serves as one large illumination region leading to considerable increase in the fill factor. Furthermore, conventional manufacturing processes can be applied to form the CMOS image sensor. The beneficial effect increases even more when advanced manufacturing techniques are used. To reduce dark current in the diode and increase depletion region for illumination between the P-doped region and the N-well, P-type ions may be implanted into the N-well to form a pin diode. Moreover, since a thick oxide layer covers the N-well, light deflecting metallic oxide layer is not formed after a self-aligned silicide process.

In addition, using a reset diode instead of a reset transistor reduces the transistor count by one, thereby increasing the fill factor further. Because the reset voltage for operating the device is a low voltage (0V), the source follower device is non-active during the reset state. Hence, the reset diode may be deleted and the drain P-doped region may be used as a reset diode instead. When the device is in a reset state, a high voltage is applied to the drain P-doped region of the source follower transistor to reset the diode. On the other hand, when the device is in an operating state, a low voltage is applied to serve as the drain terminal of the source follower transistor. Ultimately, the fill factor is further improved.

Furthermore, the CMOS image sensor can be used in combination with a voltage reading circuit such that devices within only one sensing device in an entire column are operational within a given time period. The remaining sensing devices are biased in a reset state. Therefore, the N-well voltage of the remaining devices has a voltage higher than the operating sensor. If all the output selection transistors linked to the same output line are conductive, potential at the output line is determined by the source follower device of the image sensor operating at a lower potential. According to this operating characteristic, the output selection transistor may also be eliminated so that the fill factor is further increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic diagram showing the structure of a conventional active photo diode image sensor;

FIG. 2 is a schematic diagram showing the structure of an active photo diode image sensor according to a first preferred embodiment of this invention;

FIG. 3 is an equivalent circuit diagram of the active photo diode image sensor according to the first preferred embodiment of this invention;

FIG. 4 is a schematic diagram showing the structure of an active photo diode image sensor according to a second preferred embodiment of this invention;

FIG. 5 is a schematic diagram showing the structure of an active photo diode image sensor according to a third preferred embodiment of this invention;

FIG. 6 is a schematic diagram showing the structure of an active photo diode image sensor according to a fourth preferred embodiment of this invention;

FIG. 7 is a schematic diagram showing external connections with an active photo diode image sensor according to the fourth preferred embodiment of this invention for boosting body effect; and

FIG. 8 is an equivalent circuit diagram of an active photo diode image sensor according to the fourth preferred embodiment of this invention for boosting body effect.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

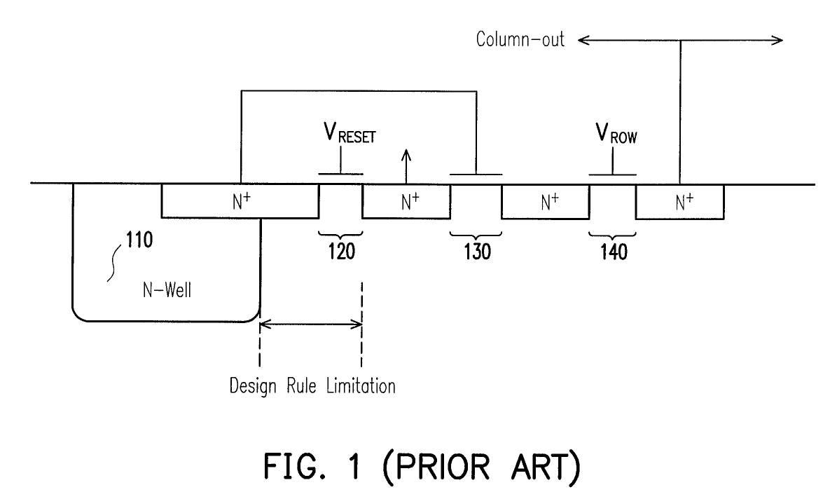

FIG. 1 is a schematic diagram showing the structure of a conventional active photo diode image sensor. As shown in FIG. 1, a conventional active photo diode image sensor includes a photo diode 110, a reset transistor 120, a source follower transistor 130 and an output selection transistor 140. The photo diode 110 is a device created by forming an N-well inside a P-type substrate. When the reset transistor 120 is conductive, the N-well is charged to a reset level. On the other hand, when the reset transistor 120 is shut down, the photo diode 110 is in a floating state. The N/P junction of the N-well produces a depletion region. If the depletion region is illuminated, electron-hole pairs generated inside the depletion will be pulled apart by local electric field. The electrons will migrate to the N-well so that potential at the N-well region drops. Size of the potential drop depends on the strength of the illuminating light beam. However, due to design rule limitations, minimal dimension of the N-well is still very large. Furthermore, distance of separation between the other three N-type transistors (N-channel MOSFET) and the N-well is also quite large leading to bigger dimension for each image sensor. Thus, fill factor is usually low and other properties of the image sensor are sub-optimal.

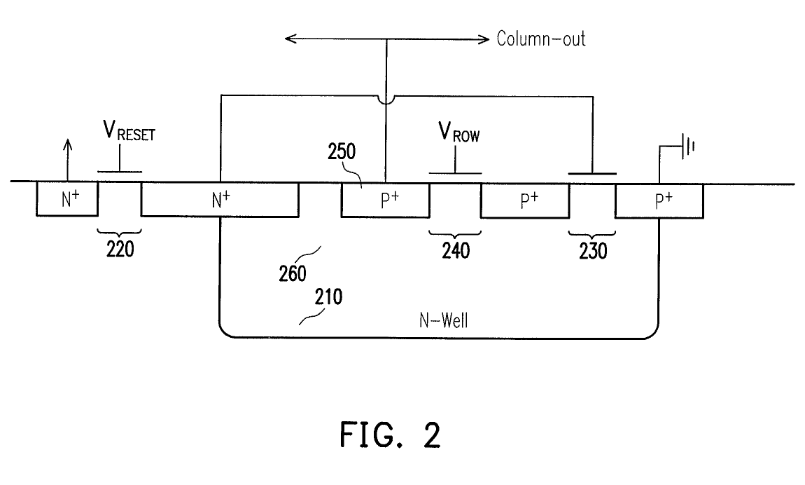

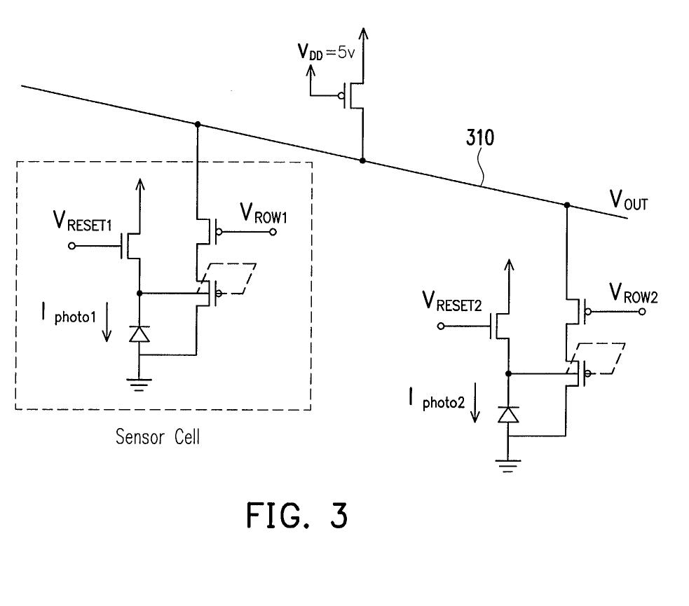

FIG. 2 is a schematic diagram showing the structure of an active photo diode image sensor according to a first preferred embodiment of this invention. FIG. 3 is an equivalent circuit diagram of the active photo diode image sensor according to the first preferred embodiment of this invention. As shown in FIG. 2, the active photo diode image sensor structure comprises a photo diode 210, a reset transistor 220, an output selection transistor 240 and a source follower transistor 230. The photo diode 210 receives a light beam to generate a diode voltage. Magnitude of the diode voltage depends on the strength of the light beam. The photo diode 210 is a device created by forming an N-well within a P-type substrate. The reset transistor 220 resets the photo diode 210 to a reset voltage level. The reset transistor 220 is a device created by forming an N-doped region within the P-type substrate but outside the N-well. The source follower transistor 230 provides an output current according to the diode voltage so that voltage level provided by the photo diode 210 may be read. The source follower transistor 230 is a device created by forming a P-doped region within the N-well. The output selection transistor 240 is a switch for choosing whether to read the voltage level from the photo diode 210 or not. Similarly, the output selection transistor 240 is a device created by forming a P-doped region within the N-well. The conventional N-type source follower transistor and output selection transistor are replaced by P-type transistors and the P-type transistors are formed inside the N-well that constitutes the photo diode. Hence, aside from some area occupied by the transistor, the entire N-well serves as one large illumination region leading to considerable increase in the fill factor. Furthermore, conventional manufacturing processes can be applied to form the CMOS image sensor. The beneficial effect increases even more when advanced manufacturing techniques are used. To reduce dark current in the diode and increase depletion region for illumination between the P-doped region and the N-well, P-type ions may be implanted into the N-well to form a pin diode. Moreover, since a thick oxide layer covers the N-well, light deflecting metallic oxide layer is not formed after a self-aligned silicide process. Ultimately, strength of the incoming light is maintained inside the depletion region after such processing step. As shown in FIG. 3, an output line 310 connects the P-doped region 250 of each device. Hence, there is a forward conduction from the P-doped region 250 to the N-well 260. To prevent forward conduction, the reading sequence must be changed accordingly. When a particular device is in operation, all the reset transistors in a column stringed to a common output line are driven into conductive mode. Hence, the bias voltage at the N-well of all non-operating devices is higher than the reset voltage, thereby preventing forward conduction from the P-doped region 250 to the N-well 260.

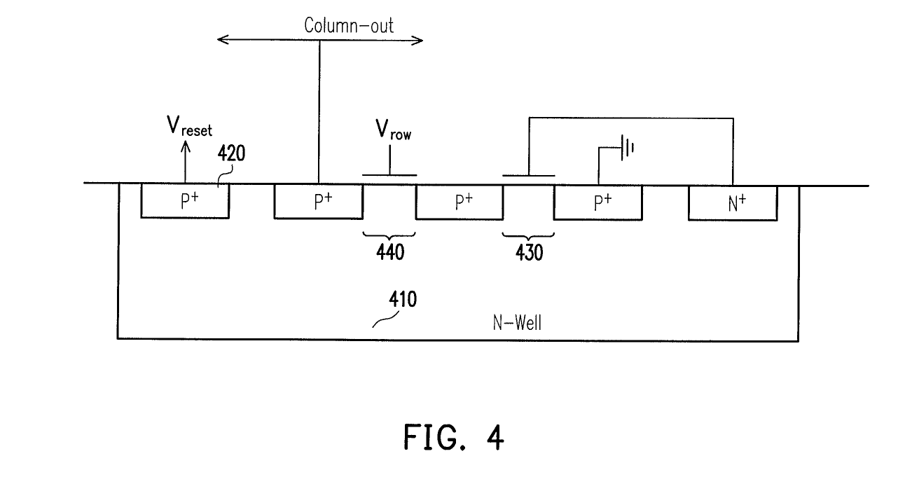

FIG. 4 is a schematic diagram showing the structure of an active photo diode image sensor according to a second preferred embodiment of this invention. As shown in FIG. 4, the active photo diode image sensor structure comprises a photo diode 410, a reset diode 420, a source follower transistor 430 and an output selection transistor 440. The active photo diode image sensor has a structure similar to the one described in the first embodiment. One major difference is that the reset mechanism is replaced by a reset diode 420. The reset diode 420 is a device created by forming a P-doped region within the N-well. When a high voltage is applied to Vᵣₑₛₑₜ to reset, the reset diode conducts and pulls the N-well to a reset level that differs from Vᵣₑₛₑₜ by a diode voltage drop (V_{D}). When a low voltage is applied to Vᵣₑₛₑₜ, the reset diode is in reverse biased so that the N-well is at a floating potential. The reset diode now changes according to illumination. Because the structure uses one less transistor, fill factor of the CMOS sensor is improved.

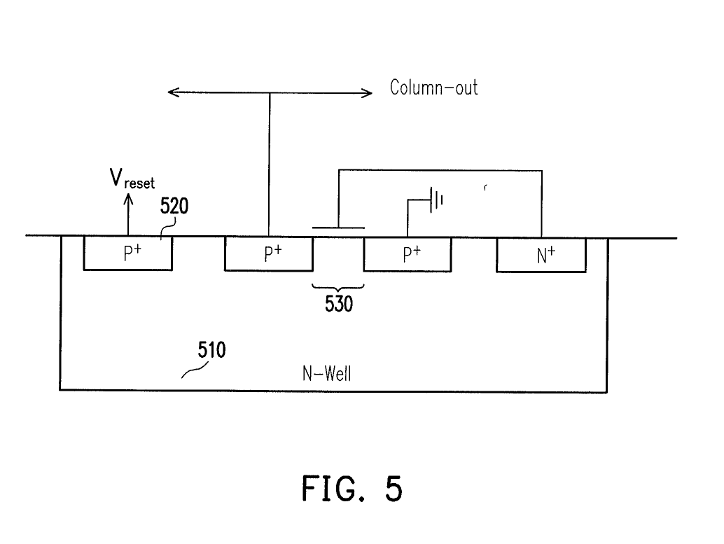

FIG. 5 is a schematic diagram showing the structure of an active photo diode image sensor according to a third preferred embodiment of this invention. As shown in FIG. 5, the active photo diode image sensor structure comprises a photo diode 510, a reset diode 520 and a source follower transistor 530. One major difference of this image sensor structure from the one described in the second embodiment is that the output selection transistor 440 is deleted. To prevent forward conduction between the P-doped output point and the N-well, the potential reading circuit operates on only one of the sensing devices in a column within a given period. Since the remaining devices are biased to a reset state, voltage at the N-well for the remaining device is higher than the operating sensor. If the output selection transistor of each device connected to the output line is conductive, potential at the output line is determined by the lower potential of the source follower device in the operating image sensor. Hence, according to the operating characteristics, the output selection transistor may be deleted. Similar argument can be applied to the active photo diode image sensor described in the first embodiment of this invention. In other words, fill factor of the image sensor structure fabricated according to the first embodiment may be further increased through the removal of the output selection transistor 240.

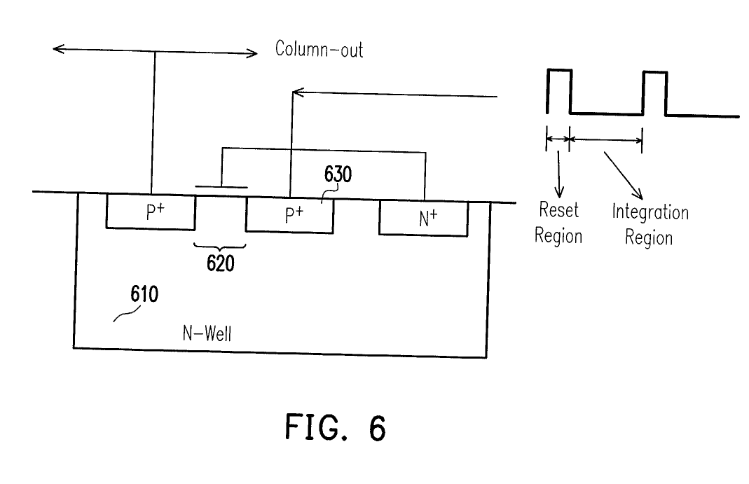

FIG. 6 is a schematic diagram showing the structure of an active photo diode image sensor according to a fourth preferred embodiment of this invention. As shown in FIG. 6, the active photo diode image sensor structure mainly comprises a photo diode 610 and a source follower transistor 620. The active photo diode image sensor structure is very similar to the one described in the third embodiment. One major difference is that the reset diode 520 is removed. The reset diode 520 can be removed because the reset terminal has a low voltage (0V) when the device is in operation and the source follower transistor 620 is non-operational in the reset state. The drain P-doped region 630 of the source follower transistor 620 may serve also as a reset diode. When the device is in a reset state, a high voltage is applied to the drain P-doped region 630 of the source follower transistor 620. The drain P-doped region 630 now serves as a reset diode. When the device is in an operating state, a low voltage is applied to the drain P-doped region 630 now also serving as a drain terminal of the source follower transistor 620. Ultimately, the fill factor is further improved. Obviously, the structure may incorporate an output selection transistor.

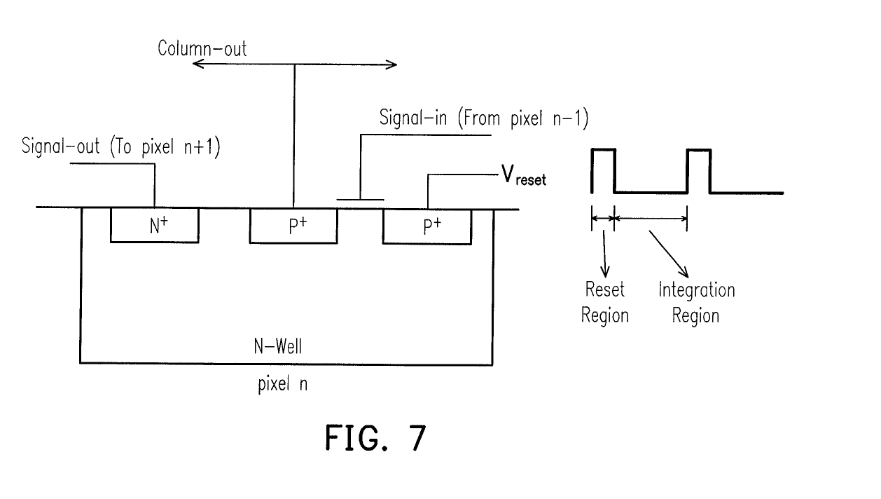

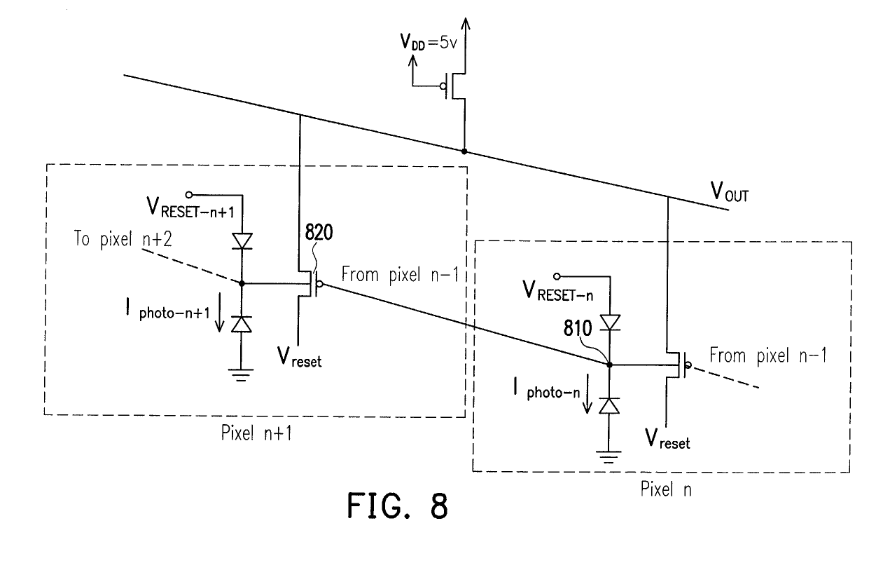

The aforementioned CMOS image sensor structures may provide an unknown amount of body effect. Hard to estimate body effect may be generated by the source follower transistor through changes in N-well voltage. FIG. 7 is a schematic diagram showing external connections with an active photo diode image sensor according to the fourth preferred embodiment of this invention for boosting body effect. FIG. 8 is an equivalent circuit diagram of an active photo diode image sensor according to the fourth preferred embodiment of this invention for boosting body effect. To reduce body effect, voltage at the N-well 810 is fed to the source follower transistor 820 of the next sensor. Since the next sensor is not in operation, the N-well is biased to a high voltage and unaffected by variation in illumination. Hence, body effect of the source follower transistor is more readily estimated.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A complementary metal-oxide-semiconductor (CMOS) image sensor structure for increasing fill factor, comprising:
a photo diode for receiving a beam of light from a light source and producing a photo diode voltage according to the strength of the light beam, wherein the photo diode is created by forming an N-well inside a P-type substrate;
a reset transistor for resetting the photo diode voltage to a reset level, wherein the reset transistor is created by forming an N-doped region in the P-type substrate but outside the N-well; and
a source follower transistor for providing an output current from the photo diode so that the photo diode voltage may be read, wherein the source follower transistor is created by forming a first and a second P-doped region within the N-well.

2. The image sensor structure of claim 1, wherein the sensor further includes an output selection transistor for choosing whether to read out the photo diode voltage or not, and the output selection transistor is created by forming a second and a third P-doped region within the N-well.

3. A complementary metal-oxide-semiconductor (CMOS) image sensor structure for increasing fill factor, comprising:
a photo diode for receiving a beam of light from a light source and producing a photo diode voltage according to the strength of the light beam, wherein the photo diode is created by forming an N-well inside a P-type substrate;
a reset diode for resetting the photo diode voltage to a reset level, wherein the reset transistor is created by forming a first P-doped region in the N-well; and
a source follower transistor for providing an output current from the photo diode so that the photo diode voltage may be read, wherein the source follower transistor is created by forming a second and a third P-doped region within the N-well.

4. The image sensor structure of claim 3, wherein the sensor further includes an output selection transistor for choosing whether to read out the photo diode voltage or not, and the output selection transistor is created by forming a third and a fourth P-doped region within the N-well.

5. A complementary metal-oxide-semiconductor (CMOS) image sensor structure for increasing fill factor, comprising:
a photo diode for receiving a beam of light from a light source and producing a photo diode voltage according to the strength of the light beam, wherein the photo diode is created by forming an N-well inside a P-type substrate; and
a source follower transistor for providing an output current from the photo diode so that the photo diode voltage may be read, wherein the source follower transistor is created by forming a source P-doped region and a drain P-doped region within the N-well such that the drain P-doped region may serve as a reset diode for resetting the photo diode voltage to a reset level.

6. The image sensor structure of claim 5, wherein the sensor further includes an output selection transistor for choosing whether to read out the photo diode voltage or not, and the output selection transistor is created by forming a P-doped region within the N-well.

7. A type of wiring connection for linking with a complementary metal-oxide-semiconductor (CMOS) image sensor capable of increasing fill factor, the image sensor at least comprising:
a photo diode for receiving a beam of light from a light source and producing a photo diode voltage according to the strength of the light beam, wherein the photo diode is created by forming an N-well inside a P-type substrate; and
a source follower transistor for providing an output current from the photo diode so that the photo diode voltage may be read, wherein the source follower transistor is created by forming a source P-doped region and a drain P-doped region within the N-well;
wherein the anode of the photo diode is connected to the gate terminal of a source follower transistor of another image sensing unit so that the photo diode voltage is output from the source follower transistor from another image sensing unit to obtain a closer estimate of body effect.
